(19) United States
(12) Patent Application Publication
(10) Pub. No.: US 2009/0061607 A1
(43) Pub. Date: Mar. 5, 2009

(54) METHOD OF MANUFACTURING PHOTOMASK AND METHOD OF MANUFACTURING SEMICONDUCTOR DEVICE

(75) Inventor: Koji Hosono, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/202,708

(22) Filed: Sep. 2, 2008

(30) Foreign Application Priority Data
Sep. 4, 2007 (JP) 2007-229031

(51) Int. Cl. H01L 21/28; G03F 1/00

(52) U.S. Cl. 438/585; 430/5; 257/E21.19

(57) ABSTRACT

According to an aspect of an embodiment, a method of manufacturing a photomask has forming a laminate over a transparent substrate, the laminate having a light-shielding layer and a hard mask layer, forming a negative resist layer over the laminate, exposing and developing the negative resist layer over the laminate to form a first resist pattern having a main pattern in a main exposure area surrounded by an outer area, etching the hard mask layer using the first resist pattern as an etching mask to form a hard mask pattern, removing the first resist pattern from the laminate; forming a positive resist layer covering the hard mask pattern over the transparent substrate, exposing and developing the positive resist layer to form a second resist pattern, the second resist pattern and a light-shielding pattern disposed in the outer area and forming an opening disclosing the hard mask pattern.

### CROSS-REFERENCE TO RELATED APPLICATION

This application is based upon and claims the benefit of priority of the prior Japanese Patent Application No. 2007-229031 filed on Sep. 4, 2007, the entire contents of which are incorporated herein by reference.

### BACKGROUND

1. Field

The embodiments discussed herein are directed to a method of manufacturing a photomask or a reticle and a method of manufacturing a semiconductor device.

2. Description of Related Art

In recent years, the manufacture of large-scale integrated circuits (LSIs) has required very fine patterning. Photomasks for use in patterning include binary photomasks that have a light-shielding layer and define translucent areas and light-shielding areas, and phase shift masks that have a phase shift layer and have the function of shifting the phase of exposure light to increase the contrast. One known phase shift mask is an attenuated phase shift mask, which forms a desired pattern in a halftone area having a transmittance of about 6%. The attenuated phase shift mask also includes a light-shielding layer at an outer area where light should be blocked.

Light-shielding layers and phase shift layers are patterned using resists. As incident energy, some resists utilize light, and other resists utilize an electron beam. In both cases, the application of energy is hereinafter referred to as “exposure”. Resists are classified into positive resists, in which an exposed area is removed by development, and negative resists, in which an unexposed area is removed by development.

In electron-beam lithography using a negative resist, only a desired pattern is exposed and developed. An area other than the pattern becomes a translucent area. By contrast, with a positive resist, an area other than a desired pattern is exposed. A light-shielding layer is left in an outer area, and the pattern is disposed at the center (see, for example, “Nyumon fotomasuku gijutsu (Guide to photomask technique)”, Kogyo Chosakai Publishing Co., Ltd., p. 41, 2006).

The accuracy with which the linewidth of a pattern is formed in a negative resist depends on the energy profile of an emitted electron beam. The patterning accuracy of a positive resist depends on the positioning accuracy of an emitted electron beam at both sides of the pattern, as well as the energy profile of the electron beam. Thus, negative resists have an advantage over positive resists in terms of the patterning accuracy.

To reduce stray light, an outer area of a photomask is desirably a light-shielding area. In the formation of a photomask having an outer light-shielding area by electron-beam lithography using a positive resist, it is sufficient not to expose the outer area. Thus, no substantial modification is needed for the exposure process. However, with a negative resist, the outer area corresponding to the light-shielding layer must be exposed. This significantly reduces the efficiency of lithography.

Japanese Laid-open Patent Publication No. 8-334885 proposes to form a light-shielding layer on a semitransparent phase shift layer except a predetermined area in an attenuated phase shift mask. More specifically, a MoSi semitransparent phase shift layer, a Cr light-shielding layer, and a positive resist layer are placed on a transparent quartz substrate. A pattern formed on the positive resist layer is then transferred to the light-shielding layer and the semitransparent phase shift layer. After another positive resist layer is subsequently formed, a target area is exposed to remove the corresponding light-shielding layer. Consequently, a halftone photomask having an outer light-shielding layer is provided.

According to Japanese Laid-open Patent Publication No. 2007-86368, a phase shift layer, a light-shielding layer, and a negative resist layer are formed on a transparent substrate in this order. A main pattern in a main area and its peripheral light-shielding pattern including a light-shielding zone are then formed on the negative resist layer. After the light-shielding pattern is transferred to the light-shielding layer, the negative resist layer is removed. A positive resist layer is then formed on the phase shift layer. A light absorption pattern widely covering the peripheral area is formed on the positive resist layer. The phase shift layer is then etched in the light absorption pattern. The light-shielding layer in the main area is removed in another process to produce a phase shift mask. In the peripheral area, the light absorption pattern of the phase shift layer, as well as the light-shielding zone, reduces stray light. The pattern to be transferred can be formed with high accuracy using a high-precision negative resist.

According to Japanese Laid-open Patent Application Publication No. 2005-62884, a Cr light-shielding layer, a hard mask layer formed, for example, of MoSi or MoSiON, and a positive resist layer are placed on a translucent substrate. After a pattern is formed on the positive resist layer, the pattern is transferred to the hard mask layer and then to the light-shielding layer. The hard mask layer is removed by etching to produce a binary mask. A phase shift mask can be produced by placing a phase inversion layer formed, for example, of MoSi between the translucent substrate and the Cr light-shielding layer. The phase inversion layer, together with the hard mask layer, is etched after the etching of the light-shielding layer. If necessary, the light-shielding layer is then etched to disclose the phase inversion layer.

According to Japanese Laid-open Patent Application Publication No. 2006-146151, a light-shielding layer that includes a Cr sublayer and a MoSi oxide sublayer is formed on a transparent substrate. The Cr sublayer cannot substantially be etched by fluorine dry etching, whereas the MoSi oxide sublayer can be etched by fluorine dry etching. An attenuated phase shift layer may be placed between the light-shielding layer and the transparent substrate.

### SUMMARY

According to an aspect of an embodiment, a method of manufacturing a photomask has forming a laminate over a transparent substrate, the laminate having a light-shielding layer and a hard mask layer, forming a negative resist layer over the laminate, exposing and developing the negative resist layer over the laminate to form a first resist pattern having a main pattern in a main exposure area surrounded by an outer area, etching the hard mask layer using the first resist pattern as an etching mask to form a hard mask pattern, removing the first resist pattern from the laminate; forming a positive resist layer covering the hard mask pattern over the transparent substrate, exposing and developing the positive resist layer to form a second resist pattern, the second resist pattern and a light-shielding pattern disposed in the outer area and forming an opening disclosing the hard mask pattern.

### BRIEF DESCRIPTION OF THE DRAWINGS

FIGS. 1A to 1H are schematic cross-sectional views of a photomask illustrating main steps for a method of manufacturing a photomask according to a first embodiment;

FIG. 2A is a schematic top view of a photomask manufactured by the method according to the first embodiment, and FIG. 2B is a schematic cross-sectional view taken along the line IIA-IIA of FIG. 2A;

FIGS. 3A to 3E are schematic cross-sectional views of a photomask according to a modification of the first embodiment;

FIGS. 4A to 4F are schematic cross-sectional views of a photomask illustrating main steps for a method of manufacturing a photomask according to a second embodiment; and

FIGS. 5A to 5D are schematic cross-sectional views of a semiconductor substrate illustrating main steps for a method of manufacturing a semiconductor device.

### DESCRIPTION OF THE PREFERRED EMBODIMENTS

A method of manufacturing a photomask will be described below with reference to the drawings.

### First Embodiment

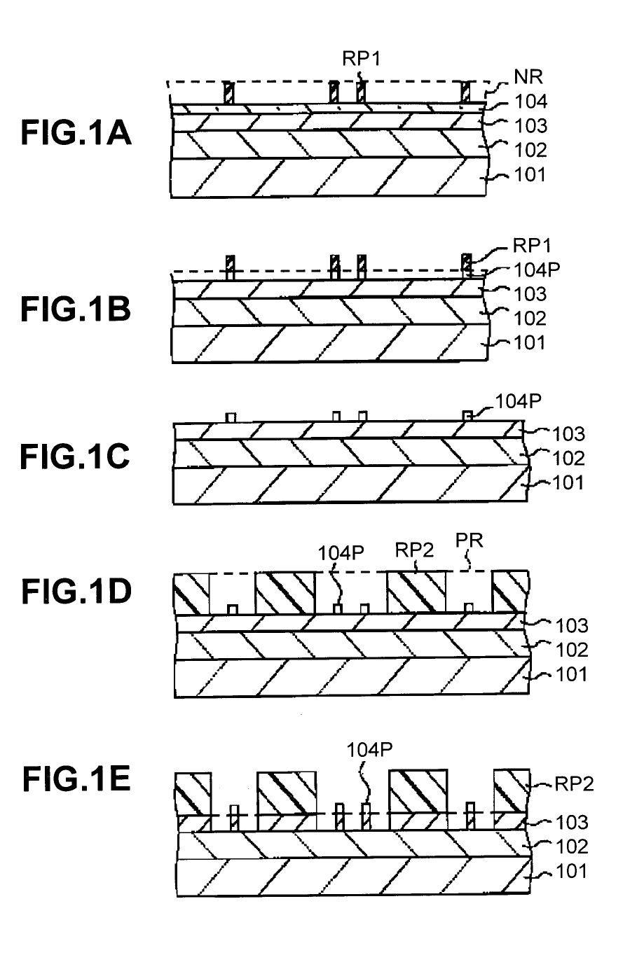

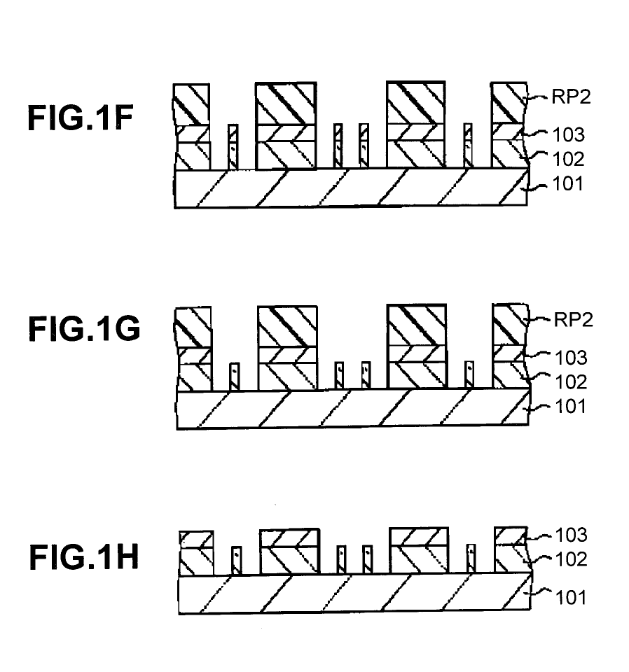

FIGS. 1A to 1H are schematic cross-sectional views of a photomask illustrating main steps for a method of manufacturing a photomask according to a first embodiment.

As illustrated in FIG. 1A, a MoSiON layer having a thickness of 66 nm is formed as an attenuated phase shift layer 102 on a transparent quartz substrate 101 by sputtering. A chromium-chromium oxide layer having a thickness of 49 nm is formed as a light-shielding layer 103 on the attenuated phase shift layer 102. A MoSiON layer having a thickness of 15 nm is formed as a hard mask layer 104 on the light-shielding layer 103 by sputtering. A chemically amplified negative resist layer NR is formed on the hard mask layer 104 by spin coating, and is exposed and developed to form a first resist pattern RP1.

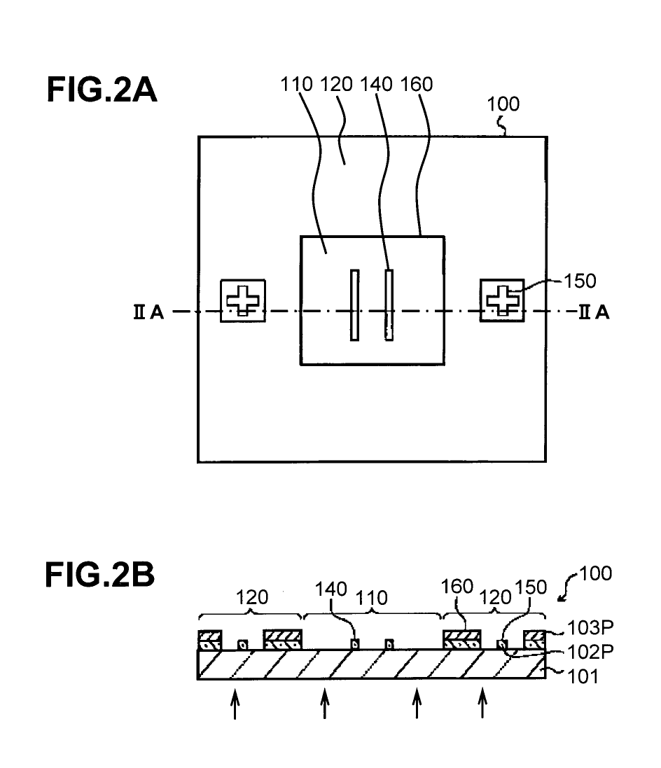

FIG. 2A is a schematic top view of a photomask manufactured by the method according to the first embodiment. FIG. 2B is a schematic cross-sectional view taken along the line IIA-IIA of FIG. 2A. As illustrated in FIG. 2A, a main exposure area 110 surrounded by an outer area 120 is a rectangular area corresponding to, for example, circuitry of a single semiconductor chip, and is a unit area to be exposed by a stepper. The unit area to be exposed may be an area composed of a plurality of semiconductor chips. In that case, the unit area is composed of a plurality of main exposure areas 110 each corresponding to a single semiconductor chip. A main pattern 140 is formed in the main exposure area 110. Register marks (fiducial marks) 150 are formed in the outer area 120. An auxiliary pattern including, for example, a test element as well as the register marks may be formed in the outer area. A light-shielding pattern 160 is formed in an area of the outer area other than the auxiliary pattern.

As illustrated in FIG. 2B, a photomask 100 includes an attenuated phase shift layer pattern 102P disposed on the quartz substrate 101 and a light-shielding layer pattern 103P disposed on the attenuated phase shift layer pattern 102P. The main pattern 140 and the register marks 150 are formed in the attenuated phase shift layer. The attenuated phase shift layer shifts the phase of halftone (about 6%) transmitting light by about 180 degrees and thereby increases the boundary contrast. The light-shielding pattern 160 is formed of the attenuated phase shift layer pattern 102P and the light-shielding layer pattern 103P and completely blocks incident light. While the main exposure area 110 is small and includes only two stripes in this embodiment for the sake of clarity, an actual main exposure area may be large and include various patterns.

Referring back to FIG. 1A, during exposure of the negative resist layer NR to an electron beam, the main pattern is exposed in the main exposure area, and the auxiliary pattern is exposed in the outer area. Only the patterns to be transferred are exposed to reduce the exposure time. However, etching without further treatments results in the formation of a wide transparent area in the outer area.

As illustrated in FIG. 1B, the hard mask layer 104 is etched using the first resist pattern RP1 as an etching mask and a gas mixture of SF₆ and He as an etching gas. This etching gas cannot etch the light-shielding layer 103 formed of chromium-chromium oxide. The first resist pattern RP1 is transferred to the hard mask layer 104, thus forming a hard mask pattern 104P having a wide opening in the outer area.

As illustrated in FIG. 1C, the first resist pattern RP1 is removed, while the light-shielding layer 103 is not etched. This leaves the hard mask pattern 104P on the light-shielding layer 103.

As illustrated in FIG. 1D, a positive resist layer PR covering the hard mask pattern 104P is formed on the light-shielding layer 103. The main exposure area and the outer area including the auxiliary pattern are exposed and developed to form openings. The positive resist layer including the openings is hereinafter referred to as a second resist pattern RP2. The hard mask pattern 104P including the main pattern and the auxiliary pattern is disposed in the openings of the second resist pattern RP2. The second resist pattern is an area that has not been exposed to the electron beam. Thus, a larger second resist pattern does not reduce the efficiency of lithography.

As illustrated in FIG. 1E, the light-shielding layer 103 is etched using the second resist pattern RP2 and the hard mask pattern 104P as an etching mask and a gas mixture of Cl₂, O₂, and He as an etching gas. A large light-shielding layer pattern 103P remains under the second resist pattern RP2. The hard mask pattern 104P and the attenuated phase shift layer 102 each formed of MoSiON are not etched by the etching gas.

As illustrated in FIG. 1F, the attenuated phase shift layer 102 is etched using a gas mixture of SF₆ and He as an etching gas.

Since the hard mask pattern 104P, which is also formed of MoSiON as in the attenuated phase shift layer 102, is etched simultaneously. While the hard mask layer may be formed of a material different from that of the attenuated phase shift layer, the hard mask layer and the attenuated phase shift layer each formed of the same material can be etched simultaneously. This eliminates the step of removing the hard mask pattern, thus simplifying the manufacturing process. For the attenuated phase shift layer formed of MoSiON, when the hard mask layer is formed of a compound containing Mo and/or Si, such as SiON, both these layers can be etched simultaneously.

If the hard mask pattern cannot be removed in the etching of the attenuated phase shift layer, the hard mask pattern is removed after the attenuated phase shift layer is etched.

As illustrated in FIG. 1G, the light-shielding layer pattern 103P is etched using a gas mixture of Cl₂, O₂, and He as an etching gas. The attenuated phase shift layer pattern 102P is not etched by this etching gas. Thus, the main pattern in the main exposure area and the auxiliary pattern are formed of the attenuated phase shift layer.

As illustrated in FIG. 1H, the second resist pattern RP2 is removed to form a photomask.

### Modification of First Embodiment

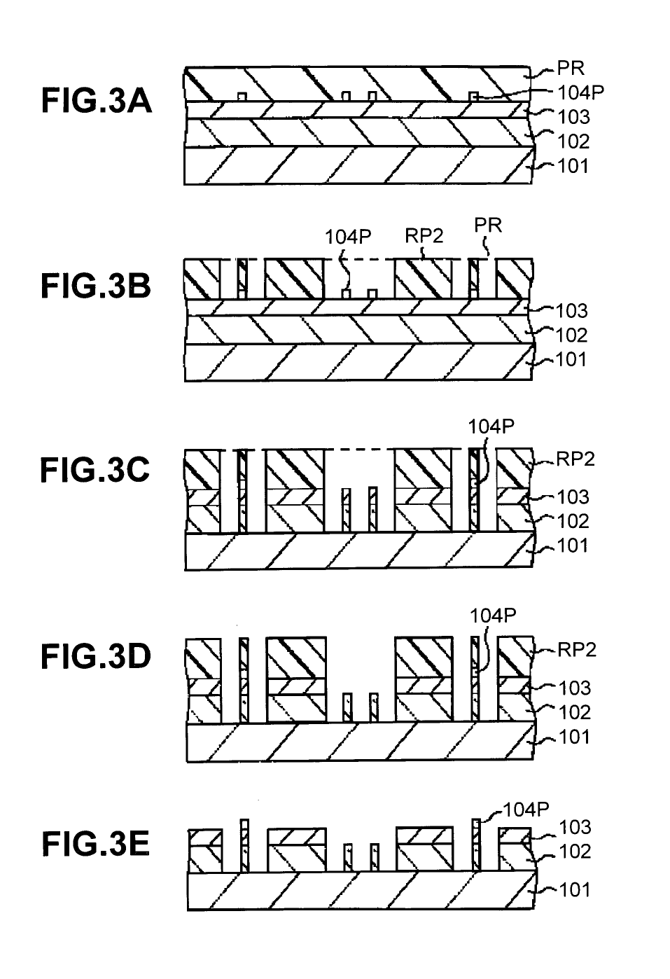

According to the first embodiment, the auxiliary pattern, which is generally a light-shielding pattern, is formed of an attenuated phase shift layer. The auxiliary pattern may be a light-shielding pattern. FIGS. 3A to 3E are schematic cross-sectional views of a photomask in which an auxiliary pattern is a light-shielding pattern, according to a modification of the first embodiment.

As illustrated in FIG. 3A, according to the steps illustrated in FIGS. 1A to 1C, a MoSiON attenuated phase shift layer 102, a chromium-chromium oxide light-shielding layer 103, and a MoSiON hard mask layer 104 are formed on a quartz substrate 101, and the hard mask layer 104 is etched using a first resist pattern as an etching mask to form a hard mask pattern 104P. After the first resist pattern is removed, a positive resist layer PR is applied to the light-shielding layer 103.

As illustrated in FIG. 3B, the positive resist layer PR is exposed and developed to form an opening in a main exposure area and an opening around an auxiliary pattern in an outer area. Since the auxiliary pattern is not to be exposed, the exposure process is complicated. The positive resist layer including the openings is hereinafter referred to as a second resist pattern RP2. A main pattern is disposed in the opening in the main exposure area of the second resist pattern RP2. The hard mask pattern 104P of the auxiliary pattern is covered with the second resist pattern.

As illustrated in FIG. 3C, the light-shielding layer 103 is etched using the second resist pattern RP2 and the hard mask pattern 104P as an etching mask and a gas mixture of Cl₂, O₂, and He as an etching gas. The attenuated phase shift layer 102 is then etched using a gas mixture of SF₆ and He as an etching gas. The light-shielding layer 103 and the attenuated phase shift layer 102 are etched while leaving the main pattern, the auxiliary pattern, and the light-shielding pattern. The hard mask pattern 104P on the main pattern is etched simultaneously with the attenuated phase shift layer 102. However, the hard mask pattern 104P on the auxiliary pattern remains under the second resist pattern RP2.

As illustrated in FIG. 3D, the light-shielding layer pattern 103P is etched using a gas mixture of Cl₂, O₂, and He as an etching gas. Thus, the main pattern in the main exposure area is formed of the attenuated phase shift layer. The light-shielding layer pattern 103P of the auxiliary pattern remains under the hard mask pattern 104P or the second resist pattern RP2.

As illustrated in FIG. 3E, the second resist pattern RP2 is removed to form a photomask. The main pattern to be transferred is formed of the attenuated phase shift layer. The auxiliary pattern is composed of the attenuated phase shift layer and the light-shielding layer. Thus, light does not pass through the auxiliary pattern.

### Second Embodiment

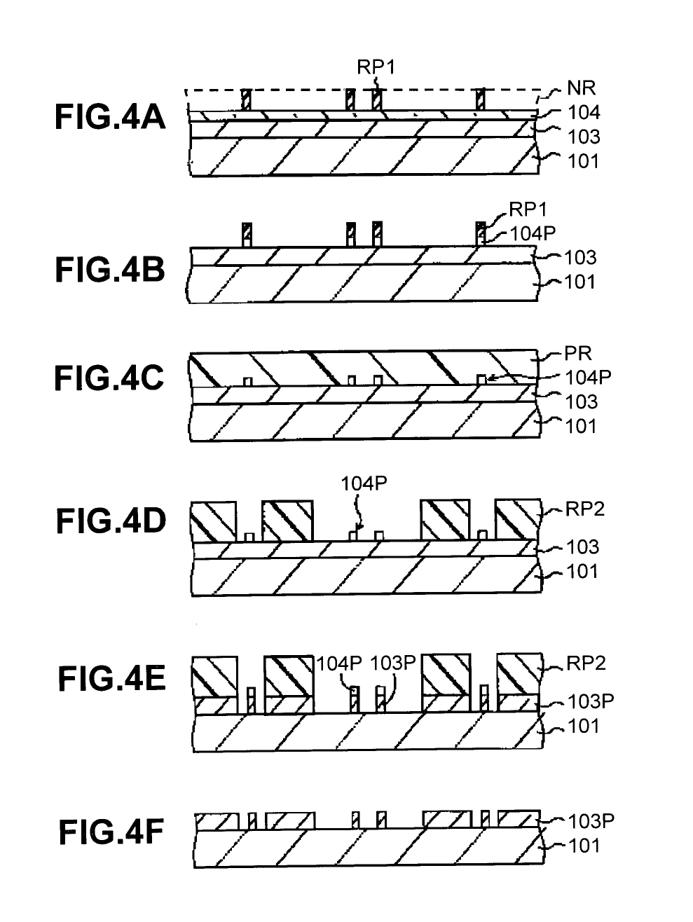

While an attenuated phase shift mask is produced in the first embodiment, a binary mask may also be produced. FIGS. 4A to 4F are schematic cross-sectional views of a photomask illustrating main steps for a method of manufacturing a photomask according to a second embodiment.

As illustrated in FIG. 4A, a chromium-chromium oxide light-shielding layer 103 and a MoSiON hard mask layer 104 are formed on a transparent quartz substrate 101 by sputtering. A chemically amplified negative resist layer NR is formed on the hard mask layer 104 by spin coating, and is exposed and developed to form a first resist pattern RP1.

As illustrated in FIG. 4B, the hard mask layer 104 is etched using the first resist pattern RP1 as an etching mask and a gas mixture of SF₆ and He as an etching gas. This etching gas cannot etch the light-shielding layer 103 formed of chromium-chromium oxide. The first resist pattern RP1 is transferred to the hard mask layer 104 to form a hard mask pattern 104P.

As illustrated in FIG. 4C, the first resist pattern RP1 is removed, while the light-shielding layer 103 is not etched. This leaves the hard mask pattern 104P on the light-shielding layer 103. A positive resist layer PR covering the hard mask pattern 104P is formed on the light-shielding layer 103.

As illustrated in FIG. 4D, a main exposure area and an outer area including an auxiliary pattern are exposed and developed to form openings. The positive resist layer including the openings is hereinafter referred to as a second resist pattern RP2. The hard mask pattern 104P including the main pattern and the auxiliary pattern is disposed in the openings of the second resist pattern RP2. The second resist pattern is an area that has not been exposed to the electron beam. Thus, a larger second resist pattern does not reduce the efficiency of lithography.

As illustrated in FIG. 4E, the light-shielding layer 103 is etched using the second resist pattern RP2 and the hard mask pattern 104P as an etching mask and a gas mixture of Cl₂, O₂, and He as an etching gas. A large light-shielding layer pattern 103P remains under the second resist pattern RP2.

As illustrated in FIG. 4F, the hard mask pattern 104P is etched, and the second resist pattern RP2 is removed to form a photomask.

### Third Embodiment

A method of manufacturing a semiconductor device using a photomask thus formed will be described below.

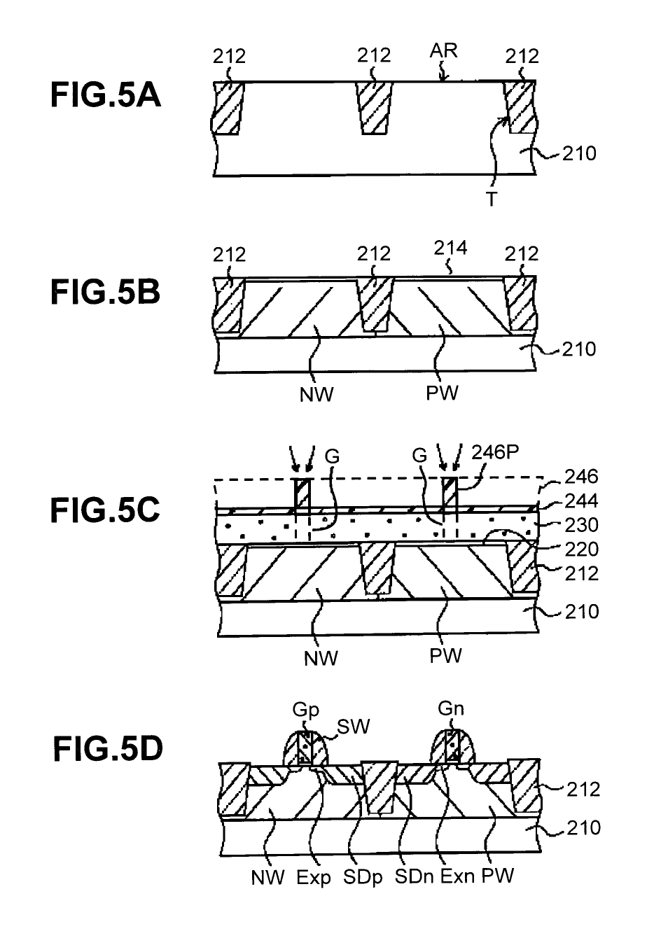

As illustrated in FIG. 5A, a silicon substrate 210 is etched using a silicon nitride hard mask to form trenches T having a depth approximately in the range of 300 to 350 nm. If necessary, the surface of the silicon substrate 210 is thermally oxidized. A silicon dioxide layer is then deposited on the silicon substrate 210 by high-density plasma (HDP) chemical vapor deposition (CVD) to fill the trenches T. An unnecessary portion of the silicon dioxide layer is removed by chemical mechanical polishing (CMP), and the hard mask is removed by wet etching. A shallow trench isolation (STI)-type device isolation region 212 thus formed defines an active region AR.

As illustrated in FIG. 5B, the surface of the active region AR is thermally oxidized to form a silicon dioxide sacrificial layer 214. Using resist masks, an n-type impurity and a p-type impurity are implanted by ion implantation to form an n-type well NW and a p-type well PW, respectively.

As illustrated in FIG. 5C, after the sacrificial layer 214 is removed, a silicon dioxide gate insulating layer 220 having a thickness approximately in the range of 1 to 3 nm is formed by thermal oxidation, if necessary, in the presence of nitrogen. A polycrystalline silicon layer 230 is formed on the gate insulating layer 220 by thermal CVD. An organic antireflection layer 244 and a resist layer 246 for an ArF excimer laser are formed on the polycrystalline silicon layer 230 by spin coating. These steps are well-known to a person skilled in the art, and various modifications are also widely known.

A semiconductor wafer illustrated in FIG. 5C is mounted on a stepper provided with the photomask or a reticle as illustrated in FIGS. 2A and 2B. The resist layer 246 is irradiated with an ArF excimer laser beam from the direction of the arrow illustrated in FIG. 2B via a one-tenth- to one-fifth-reduction projection exposure system. Exposure conditions may be as follows: numerical aperture (NA)=0.7, ½ annular illumination (σ value: 0.425/0.85), and exposure=210 J/cm². A scanner may be used in place of the stepper.

A resist pattern 246P is then formed by post-baking and development. The antireflection layer 244 and the polycrystalline silicon layer 230 are etched using the resist pattern 246P as an etching mask to form gate electrodes G. Variations in the dimensions of the gate electrodes are 2 nm (3 sigmas) in a single shot.

As illustrated in FIG. 5D, a p-type impurity and an n-type impurity are implanted in the n-type well NW and the p-type well PW, respectively, by ion implantation to form extensions Exp and Exn, respectively. An insulating layer, such as a silicon dioxide layer, is formed on the top surface by CVD. The insulating layer on a horizontal surface is removed by anisotropic etching, such as reactive ion etching (RIE), leaving the insulating layer SW only on the sidewalls of the gate electrodes G. A p-type impurity and an n-type impurity are implanted in the n-type well NW and the p-type well PW, respectively, by ion implantation to form deep source/drain regions SDp and SDn, respectively, each containing the respective concentrated impurities. After the formation of an interlayer insulating layer and wiring, a semiconductor device is manufactured.

While the present technique has been described in terms of the preferred embodiments, the present technique is not limited to the embodiments. A person skilled in the art will recognize that various modifications, substitutions, improvements, and combinations can be made in the embodiments.

What is claimed is:

1. A method of manufacturing a photomask comprising:
forming a laminate having a light-shielding layer and a hard mask layer over a transparent substrate;
forming a negative resist layer over the laminate;
exposing and developing the negative resist layer over the laminate to form a first resist pattern having a main pattern in a main exposure area surrounded by an outer area;
etching the hard mask layer using the first resist pattern as an etching mask to form a hard mask pattern;
removing the first resist pattern from the laminate;
forming a positive resist layer covering the hard mask pattern over the transparent substrate;
exposing and developing the positive resist layer to form a second resist pattern, the second resist pattern and a light-shielding pattern disposed in the outer area and forming an opening disclosing the hard mask pattern; and
etching the light-shielding layer using the hard mask pattern in the opening and the second resist pattern as an etching mask.

2. The method according to claim 1, wherein the first resist pattern comprises an auxiliary pattern formed at the outer area.

3. The method according to claim 1, wherein the light-shielding layer and the hard mask layer are formed by a material which is able to be etched respectively.

4. The method according to claim 3, wherein the light-shielding layer comprises at least chromium layer or chromium oxide layer, and the hard mask layer comprises a compound comprising Mo or Si.

5. The method according to claim 3, further comprising:
removing the second resist pattern and forming a binary mask after the etching the light-shielding layer using the hard mask pattern in the opening and the second resist pattern as the etching mask.

6. The method according to claim 1, wherein the laminate comprises an attenuated phase shift layer between the transparent substrate and the light-shielding layer, the method further comprising:
etching the attenuated phase shift layer and the hard mask pattern, the attenuated phase shift layer being exposed, after the etching the light-shielding layer;
etching the light-shielding layer in the opening using the second resist pattern as a mask, and exposing the attenuated phase shift layer; and
removing the second resist pattern from the transparent substrate.

7. The method according to claim 6, wherein the attenuated phase shift layer comprises an etching property different from the etching property of the light-shielding layer, and the attenuated phase shift layer has the same etching property as the hard mask.

8. The method according to claim 6, wherein the attenuated phase shift layer comprises Mo or Si.

9. The method according to claim 6, the etching the attenuated phase shift layer and the hard mask pattern etches the hard mask pattern in the opening.

10. A method of manufacturing a semiconductor device comprising:
forming a gate insulating layer over an active region of a semiconductor substrate;
forming a polysilicon layer covering the gate insulating layer over the semiconductor substrate;
applying a photoresist to the polysilicon layer to form a photoresist layer;
transferring a main pattern and an auxiliary pattern individually to the photoresist layer by exposing the photoresist layer with an exposure apparatus using an attenuated phase shift mask that comprises the main pattern, the auxiliary pattern, and a light-shielding pattern, the main pattern being formed of an attenuated phase shift layer in a main exposure area surrounded by an outer area, the auxiliary pattern being formed of the attenuated phase shift layer in the outer area, and the light-shielding pattern being formed of the attenuated phase shift layer and a light-shielding layer formed over the attenuated phase shift layer, the light-shielding pattern being disposed in an area of the outer area other than an area in which the auxiliary pattern is formed;
developing the photoresist layer; and
etching the polysilicon layer using the developed photoresist layer as an etching mask.
